(19) United States
(12) Patent Application Publication
(10) Pub. No.: US 2012/0220120 A1
(43) Pub. Date: Aug. 30, 2012

(54) METHOD FOR FABRICATING BURIED BIT LINE IN SEMICONDUCTOR DEVICE

(76) Inventor: Hee-Sung KANG, Gyeonggi-do (KR)

(21) Appl. No.: 13/333,997

(22) Filed: Dec. 21, 2011

(30) Foreign Application Priority Data
Feb. 25, 2011 (KR) 10-2011-0017005

(51) Int. Cl. H01L 21/283

(52) U.S. Cl. 438/653; 257/E21.159

(57) ABSTRACT

A method for fabricating a buried bit line in a semiconductor device includes forming a liner oxide layer over the entire surface of a substrate having bodies isolated by a trench, selectively etching the liner oxide layer contacted with one side surface of the trench to a given depth, forming a sacrifice layer at a larger height than an etched surface of the liner oxide layer wherein the sacrifice layer partially fills the trench to the larger height, forming a liner nitride layer on sidewalls of the trench over the sacrifice layer, removing the sacrifice layer to expose a part of a body at the one side surface of the trench, forming a barrier layer along the entire surface of the resultant structure including the liner oxide layer, and forming a buried bit line over the barrier layer to be contacted with the exposed part of the body.

### CROSS-REFERENCE TO RELATED APPLICATIONS

The present application claims priority of Korean Patent Application No. 10-2011-0017005, filed on Feb. 25, 2011, which is incorporated herein by reference in its entirety.

### BACKGROUND

1. Field

Exemplary embodiments of the present invention relate to semiconductor fabrication technology, and more particularly, to a method for fabricating a buried bit line in a semiconductor device.

2. Description of the Related Art

As semiconductor devices are highly integrated, device scaling is approaching a limit in terms of process and device characteristics. In particular, the miniaturization of cells in a memory device having a high integration degree has a technical limit. In order to overcome such a limit, a cell switching transistor becoming an obstacle to high integration is formed with a three-dimensional structure. However, in such a structure in which a word line contact and a bit line contact are simultaneously formed over a cell transistor, scaling is difficult. Accordingly, a vertical transistor having a bit line provided under a cell transistor has been proposed.

FIGS. 1A and 1B are cross-sectional views explaining a conventional method for fabricating a buried bit line.

Referring to FIG. 1A, a hard mask 12 is formed over a substrate 11, and the substrate 11 is etched using the hard mask 12 as an etch barrier. Accordingly, a trench 13 is formed, and bodies 14 isolated by the trench 13 are formed.

A liner oxide layer 15 is formed on the sidewalls and bottom of the trench 13, and a liner nitride layer 17 is formed over the liner oxide layer 15 on the sidewalls of the trench 13. A gap-fill layer 16 is formed over a bottom portion of the liner oxide layer 15 so as to partially gap-fill the trench 13. The liner nitride layer 17 is formed by the following process: after the gap-fill layer 16 is formed, a portion of the liner oxide layer 15 over the gap-fill layer 16 is selectively slimmed, and the liner nitride layer 17 is formed on the slimmed liner oxide layer 15.

A spacer 18 is formed on the liner nitride 17 over the gap-fill layer 16. The spacer 18 may include titanium nitride (TiN).

A sacrifice layer 19 is formed over the gap-fill layer 16, and a polysilicon layer (20A and 20B) is formed as an etching barrier layer over the entire surface of the resultant structure including the sacrifice layer 19.

Tilt implantation 21 is performed on the polysilicon layer (20A and 20B).

After the tilt implantation 21 is performed, the polysilicon layer (20A and 20B) is divided into a doped portion 20A and an undoped portion 20B, and the undoped portion 20B has a relatively high etching speed.

Referring to FIG. 2B, the undoped polysilicon layer 20B having a relatively high etching speed is selectively removed due to a difference in etching speed.

Furthermore, the exposed spacer 18 is removed. The spacer 18 may be removed by wet etching.

When the spacer 18 is removed, a gap 22 is formed between the sacrifice layer 19 and a sidewall of the trench 13, and the gap 22 is used to form a contact region.

In the conventional method, the processes by employing the tilt implantation and the wet etching of TiN are typically performed to form the contact region.

However, the contact region process in the conventional method may require a large number of processes, and high-level patterning technique by using the tilt implantation should be performed. Furthermore, there may many difficulties in dipping out the spacer through a narrow space. Therefore, it may be difficult to regularly form the contact region in position.

### SUMMARY

An exemplary embodiment of the present invention is directed to a method for fabricating a buried bit line in a semiconductor device, which is capable of uniformizing the formation position of a contact region and simplifying a process.

In accordance with an exemplary embodiment of the present invention, a method for fabricating a buried bit line in a semiconductor device includes forming a liner oxide layer over the entire surface of a substrate having bodies isolated by a trench, selectively etching the liner oxide layer contacted with one side surface of the trench to a given depth, forming a sacrifice layer at a larger height than an etched surface of the liner oxide layer wherein the sacrifice layer partially fills the trench to the larger height, forming a liner nitride layer on sidewalls of the trench over the sacrifice layer, removing the sacrifice layer to expose a part of a body at the one side surface of the trench, forming a barrier layer along the entire surface of the resultant structure including the liner oxide layer, and forming a buried bit line over the barrier layer to be contacted with the exposed part of the body.

The forming of the sacrifice layer may include coating the liner oxide layer with a photoresist layer to fill the trench, performing blanket exposure on the photoresist layer, and developing the exposed part of the photoresist layer.

The method may further include slimming the liner oxide layer over the sacrifice layer, before the forming of the liner nitride layer. The slimming of the liner oxide layer may be performed by wet etching.

The forming of the liner nitride layer may include forming a liner nitride layer over the entire surface of the substrate including the liner oxide layer, and etching the liner nitride layer to remain on the sidewalls of the trench.

The etching of the liner oxide layer may include forming a gap-fill layer over the liner oxide layer such that the gap-fill layer fills the trench, forming a mask pattern over the gap-fill layer, and selectively etching the liner oxide layer at one sidewall of the trench using the mask pattern.

The barrier layer may include a stacked structure of titanium and titanium nitride. The method may further include forming metal silicide at the exposed part of the body, before the forming of the buried bit line. In the forming of the metal silicide, a heat treatment may be performed to cause the exposed part of the body and the barrier layer to react with each other.

In accordance with an exemplary embodiment of the present invention, a method for fabricating a buried bit line in a semiconductor device includes forming a liner oxide layer over the entire surface of a substrate having bodies isolated by a trench, selectively etching the liner oxide layer contacted with one side surface of the trench to have a first given height from the bottom of the trench, forming a liner nitride layer on sidewalls of the trench, wherein the liner nitride layer is formed over a second given height of the trench and the second height is larger than the first given height to expose a part of a body at the one side surface of the trench, and forming a buried bit line over the barrier layer to be contacted with the exposed part of the body.

### BRIEF DESCRIPTION OF THE DRAWINGS

FIGS. 1A and 1B are cross-sectional views explaining a conventional method for fabricating a buried bit line.

FIGS. 2A to 2G are cross-sectional views explaining a method for fabricating a buried bit line in a semiconductor device in accordance with an exemplary embodiment of the present invention.

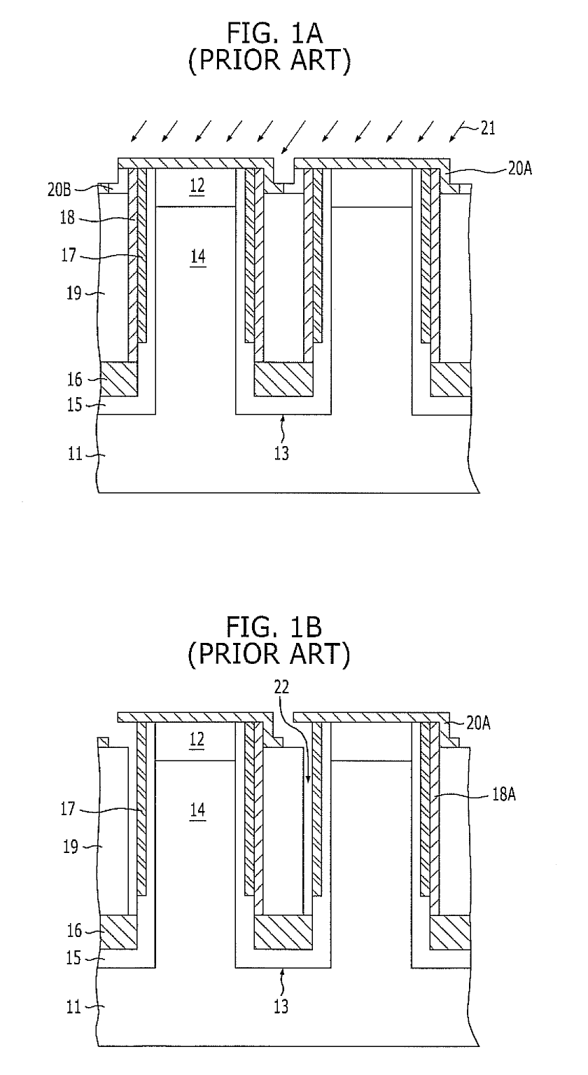

### DETAILED DESCRIPTION

Exemplary embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention.

The drawings are not necessarily to scale and in some instances, proportions may have been exaggerated in order to clearly illustrate features of the embodiments. When a first layer is referred to as being “on” a second layer or “on” a substrate, it not only refers to a case where the first layer is formed directly on the second layer or the substrate but also a case where a third layer exists between the first layer and the second layer or the substrate.

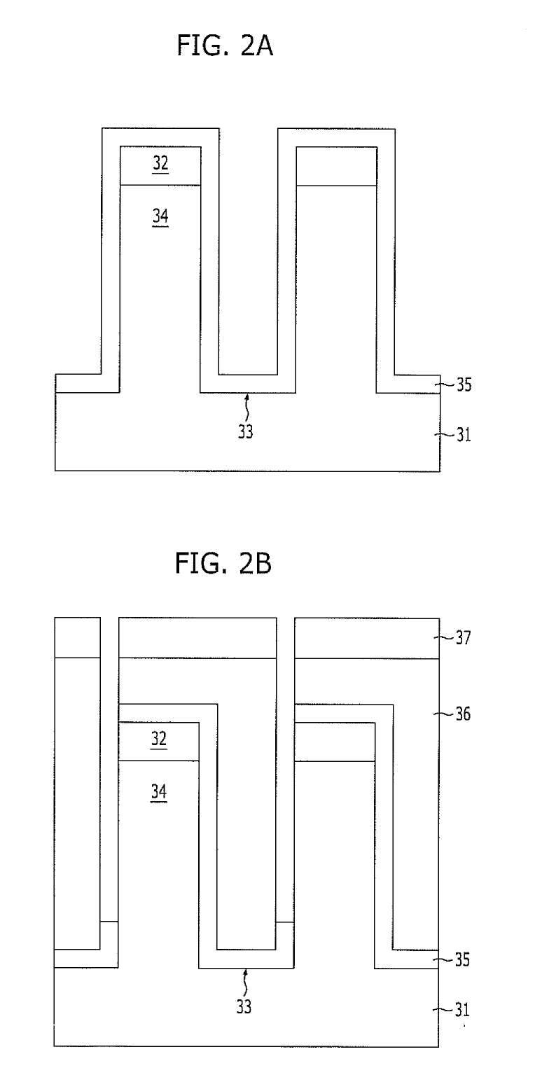

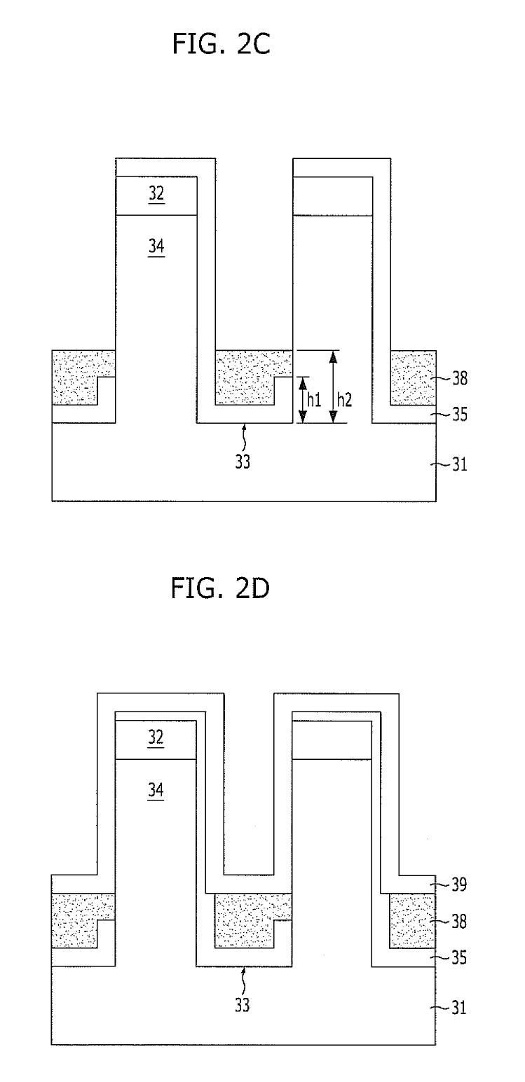

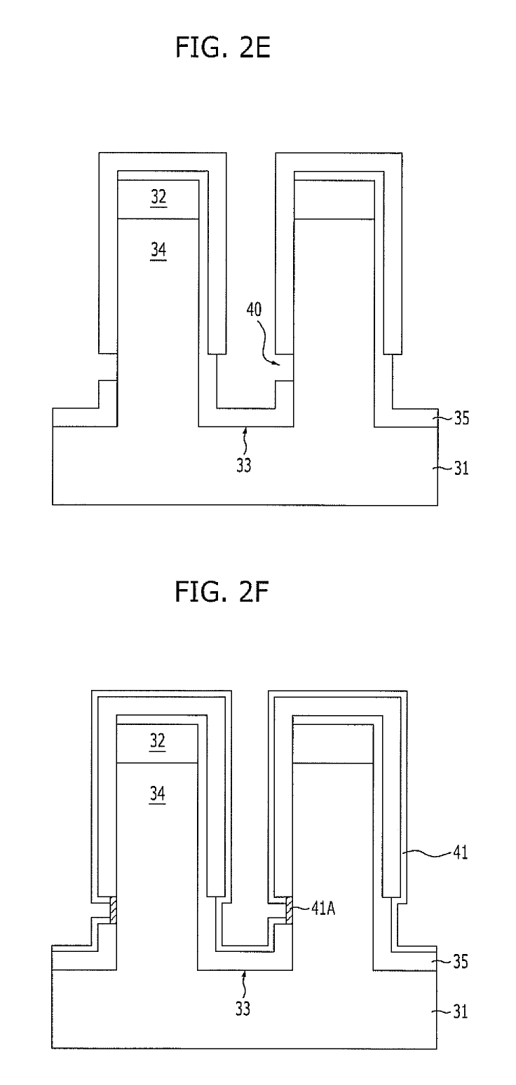

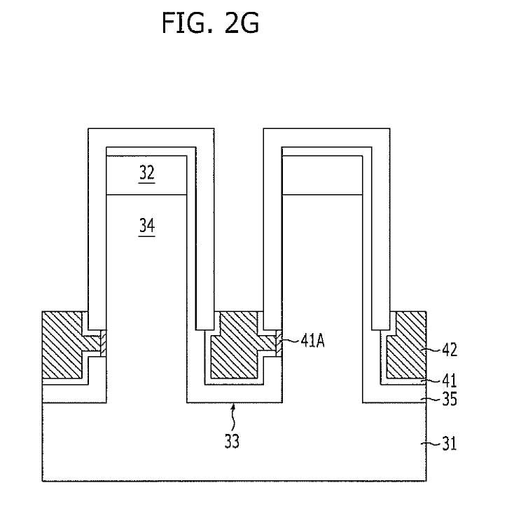

FIGS. 2A to 2G are cross-sectional views explaining a method for fabricating a buried bit line in a semiconductor device in accordance with an exemplary embodiment of the present invention.

Referring to FIG. 2A, a hard mask layer 32 is formed over a substrate 31, and the substrate 31 is etched using the hard mask layer 32 as an etch barrier to form a plurality of bodies 34. The bodies 34 are isolated by a trench 33. A liner oxide layer 35 is formed on the entire surface of the resultant structure including the bodies 34. The liner oxide layer 35 may be formed of a dielectric layer, and may include oxide such as silicon oxide.

Referring to FIG. 2B, a gap-fill layer 36 is formed over the liner oxide layer 35 so as to gap-fill the trench 33. The gap-fill layer 36 may be formed of a material having an etching selectivity with respect to the liner oxide layer 35 and the substrate 31.

A mask pattern 37 is formed over the gap-fill layer 36. The mask pattern 37 is formed by coating the gap-fill layer 36 with a photoresist layer and patterning the photoresist layer through exposure and development such that the patterned photoresist layer overlaps the upper portion of the liner oxide layer 35 contacted with one sidewall of the trench 33.

The gap-fill layer 36 and the liner oxide layer 35 are partially etched using the mask pattern 37 as an etch barrier to expose one side surface of the trench 33. At this time, the one side surface of the trench 33 is not completely exposed, but the liner oxide layer 35 may be left to a predetermined thickness to provide a contact region between the body 34 and a subsequent buried bit line.

As such, as the liner oxide 35 is etched using the mask pattern 37, a position, where a junction region is to be formed, may be regularly set or arranged.

Referring to FIG. 2C, the mask pattern 37 and the gap-fill layer 36 are removed.

A sacrifice layer 38 is formed to fill a part of the trench 33 at a height h2, as a second given height, larger than a height h1, as a first given height, ranging from the bottom surface of the trench 33 to the etched surface of the liner oxide 35. The sacrifice layer 38 is formed by the following process: a photoresist layer is applied to fill the trench 33, blanket exposure is performed, and the exposed portion is developed to partially fill the trench 33.

At this time, the blanket exposure is performed while exposure energy is controlled in such a manner that the sacrifice layer 38 remains at a larger height than the etched surface of the liner oxide layer 35. For example, assuming that the etched surface of the liner oxide layer 35 has a height h1, ranging from the bottom of the trench 33 to the etched surface, and the upper surface of the sacrifice layer 38 has a height h2, ranging from the bottom of the trench 33 to the upper surface, a region corresponding to a height difference between the sacrifice layer 38 and the liner oxide layer 35, i.e., h2-h1 becomes a contact region. Therefore, considering the region, the remaining thickness of the sacrifice layer 38 may be controlled.

A cleaning process and a baking process are subsequently performed.

Referring to FIG. 2D, a liner nitride layer 39 is formed along the entire surface of the resultant structure including the sacrifice layer 38. The liner nitride layer 39 includes nitride such as silicon nitride.

Before the liner nitride layer 39 is formed, the liner oxide layer 35 exposed over the sacrifice layer 38 is slimmed. The liner oxide layer 35 may be slimmed by using wet etching. Therefore, the liner oxide layer 35 exposed over the sacrifice layer 38 has a smaller thickness than the liner oxide layer 35 surrounding the sacrifice layer 38.

Referring to FIG. 2E, the liner nitride layer 39 is etched so as to remain on the sidewalls of the trench 33 and the hard mask layer 32.

The sacrifice layer 38 shown in FIG. 2D is exposed by the etching of the liner nitride layer 39.

The exposed sacrifice layer 38 is removed. When the sacrifice layer 38 is formed of, for example, photoresist, the sacrifice layer 38 may be removed by dry etching, and the dry etching may include an oxygen strip process.

As the sacrifice layer 38 is removed, a spacer exposing a part of the body 34 at one sidewall of the trench 33 is formed between the liner nitride 39 and the liner oxide 35. This space becomes a contact region 40 which couples a subsequent buried bit line to the body 34.

As such, the liner oxide layer 35 is etched to define the position of the contact region 40, and the remaining height of the sacrifice layer 38 is controlled to define the width of the contact region 40. Therefore, it may be possible to regularly control the formation of the desired contact region 40, while simplifying the process.

Referring to FIG. 2F, a barrier layer 41 is formed along the entire surface of the resultant structure including the liner nitride layer 39. The barrier layer 41 has a stacked structure of, for example, titanium (T) and titanium nitride (TiN).

Before the barrier layer 41 is formed, a junction region (not illustrated) may be formed in a part of the body 34 exposed by the contact region 40. The junction region may be formed by an implantation method and a plasma doping method. Furthermore, the junction region may be formed by applying a doped layer such as doped polysilicon and then performing a heat treatment. A dopant doped into the doped layer may include, for example, N-type impurities such as phosphorus (P). Therefore, the junction region becomes an N-type junction.

Through a heat treatment, silicide 41A is formed at a part of the exposed body 34, that is, the contact region 40. The silicide 41A is an ohmic contact between the junction region and a subsequent buried bit line, and serves to reduce contact resistance. The silicon body and titanium of the barrier layer 41 react with each other to form titanium silicide.

Referring to FIG. 2G, a buried bit line 42 is formed to be coupled to the junction region and partially fill the trench 33. First, a tungsten layer is formed to gap-fill the space over the barrier layer 41, and a planarization and etch-back process is performed in such a manner that the tungsten layer has such a thickness as to partially fill the trench 33. While the planarization and etch-back process of the tungsten layer is performed, the barrier layer 41 is etched together so as to remain to the same height as the tungsten layer.

As such, since the buried bit line 42 is formed of a metal layer, resistance decreases. Furthermore, since only one buried bit line 42 is coupled to one junction region, it may be possible to achieve high integration.

The method for fabricating a buried bit line in a semiconductor device in accordance with the exemplary embodiment of the present invention, the position of the contact region may be regularly and accurately controlled, and the process may be simplified.

While the present invention has been described with respect to the specific embodiments, it will be apparent to those skilled in the art that various changes and modifications may be made without departing from the spirit and scope of the invention as defined in the following claims.

What is claimed is:

1. A method for fabricating a buried bit line in a semiconductor device, comprising:
forming a liner oxide layer over the entire surface of a substrate having bodies isolated by a trench;
selectively etching the liner oxide layer contacted with one side surface of the trench to a given depth;
forming a sacrifice layer at a larger height than an etched surface of the liner oxide layer wherein the sacrifice layer partially fills the trench to the larger height;
forming a liner nitride layer on sidewalls of the trench over the sacrifice layer;
removing the sacrifice layer to expose a part of a body at the one side surface of the trench;
forming a barrier layer along the entire surface of the resultant structure including the liner oxide layer; and
forming a buried bit line over the barrier layer to be contacted with the exposed part of the body.

2. The method of claim 1, wherein the forming of the sacrifice layer comprises:
coating the liner oxide layer with a photoresist layer to fill the trench;
performing blanket exposure on the photoresist layer; and
developing the exposed part of the photoresist layer.

3. The method of claim 1, further comprising slimming the liner oxide layer over the sacrifice layer, before the forming of the liner nitride layer.

4. The method of claim 3, wherein the slimming of the liner oxide layer is performed by wet etching.

5. The method of claim 1, wherein the forming of the liner nitride layer comprises:
forming a liner nitride layer over the entire surface of the substrate including the liner oxide layer; and
etching the liner nitride layer to remain on the sidewalls of the trench.

6. The method of claim 1, wherein the etching of the liner oxide layer comprises:
forming a gap-fill layer over the liner oxide layer such that the gap-fill layer fills the trench;
forming a mask pattern over the gap-fill layer; and
selectively etching the liner oxide layer at one sidewall of the trench using the mask pattern.

7. The method of claim 1, wherein the barrier layer comprises a stacked structure of titanium and titanium nitride.

8. The method of claim 8, further comprising forming metal silicide at the exposed part of the body, before the forming of the buried bit line.

9. The method of claim 8, wherein, in the forming of the metal silicide, a heat treatment is performed to cause the exposed part of the body and the barrier layer to react with each other.

10. The method of claim 8, wherein the metal silicide comprises titanium silicide.

11. The method of claim 11, wherein the forming of the buried bit line comprises:
forming a polysilicon layer over the barrier layer such that the polysilicon layer fills the trench; and
etching the polysilicon layer to fill a part of the trench.

12. A method for fabricating a buried bit line in a semiconductor device, comprising:
forming a liner oxide layer over the entire surface of a substrate having bodies isolated by a trench;
selectively etching the liner oxide layer contacted with one side surface of the trench to have a first given height from the bottom of the trench;
forming a liner nitride layer on sidewalls of the trench, wherein the liner nitride layer is formed over a second given height of the trench and the second height is larger than the first given height to expose a part of a body at the one side surface of the trench; and
forming the buried bit line over a barrier layer to be contacted with the exposed part of the body.

13. The method of claim 12, wherein the forming of the liner nitride layer comprises:
forming a sacrifice layer by partially filling the trench to the second given height;
forming a liner nitride layer on sidewalls of the trench over the sacrifice layer; and
removing the sacrifice layer to expose the part of the body at the one side surface of the trench.

14. The method of claim 12, wherein the forming of the buried bit line over the barrier layer comprises:
forming a barrier layer along the entire surface of the resultant structure including the liner oxide layer; and
forming a buried bit line over the barrier layer to be contacted with the exposed part of the body.

15. The method of claim 13, wherein the forming of the liner nitride layer comprises slimming the liner oxide layer over the sacrifice layer, before the forming of the liner nitride layer.
